(19) United States
(12) Patent Application Publication
(10) Pub. No.: US 2017/0068291 A1
(43) Pub. Date: Mar. 9, 2017

(54) Cellular with a Heat Pumping Device

(71) Applicants: Yi-Chuan CHENG, Yongjing Township (TW); Kuo-Ching CHIANG, New Taipei City (TW)

(72) Inventors: Yi-Chuan CHENG, Yongjing Township (TW); Kuo-Ching CHIANG, New Taipei City (TW)

(21) Appl. No.: 15/179,959

(22) Filed: Jun. 10, 2016

Related U.S. Application Data
(63) Continuation-in-part of application No. 13/037,361, filed on Mar. 1, 2011.
Application No. 13/037,361 is a continuation-in-part of application No. 11/819,124, filed on Jun. 25, 2007, now abandoned.
Application No. 11/819,124 is a continuation-in-part of application No. 10/900,766, filed on Jul. 28, 2004, now Pat. No. 7,388,549.

(51) Int. Cl. G06F 1/20; H01L 23/427; G06F 13/40; H01L 35/28; H01L 31/0525; H01L 23/38; H01L 35/34

(52) U.S. Cl. CPC G06F 1/20; H01L 23/38; H01L 23/427; H01L 35/34; H01L 35/28; H01L 31/0525; G06F 13/4022

(57) ABSTRACT

The present invention discloses a portable device, comprising: a first processor, a first cache coupled to the first processor, a second processor and a second cache coupled to the second processor. A cross-processor data transfer interface is coupled to the first cache and the second cache, to determine how to transfer data, via the first processor and the second processor, and to assign task duties to the first processor or the second processor. A heat pumping device is coupled to the first processor or the second processor. The heat pumping device includes at least one heat pipe or has an enclosed space filled with at least one phase change material.

### CROSS REFERENCE TO RELATED APPLICATIONS

This application is a continuation-in-part of Ser. No. 13/037,361, filed on Mar. 1, 2011, which is a continuation-in-part of Ser. No. 11/819,124, filed on Jun. 25, 2007, which is a continuation-in-part of Ser. No. 10/898,761, filed on Jul. 26, 2004, and a continuation-in-part of Ser. No. 10/900,766, filed on Jul. 28, 2004.

### TECHNICAL FIELD

The present invention relates a cellular, and more particularly, a cellular with a heat pumping device.

### BACKGROUND OF RELATED ARTS

Recently, the issues of environmental protection is more serious than ever, the greenhouse effect and oil shortage impacts to the earth and global environment, continuously. Because of the issue mentioned above, manufactures endeavor to develop green product such as solar cell to save the energy. Solar cells are a kind of optoelectronic semiconductor device for transforming light into electricity.

Conventional thermal transfer occurs only through conduction. Heat transfer associates with carriage of the heat by a substance. Peltier effect is the reverse of the Seebeck effect. When a current is passed through two conductors such as metals or semiconductors (n-type and p-type) connected to each other at two junctions (Peltier junctions), a heat difference is created between the two junctions. Namely, current drives a heat transfer from one junction to the other, one junction cools off while the other heats up. When electrons flow from a region of high density to a region of low density, they expand and cool. The direction of transfer will be changed when the polarity is revised and thus the sign of the heat absorbed/evolved. The effect may transfer heat from one side of the device to the other. When current moves from the hotter end to the colder end, it is moving from a high to a low potential, so there is an evolution of energy. JP 2005-116698A disclosed a bulk device constructing by p and n type semiconductor bulk. All the pluralities of Peltier devices are thick, and is unlikely formed over a substrate of glass or chip package. Obliviously, what is desired is a thinner cooler with energy saving properties.

### SUMMARY

A method of forming Peltier diodes, comprises providing a substrate; forming a conductive pattern over the substrate; forming an isolation layer over the conductive pattern; forming cavities in the isolation layer and refilling a semiconductor material into the cavities, thereby forming a first and a second semiconductors, wherein the first and second semiconductors are formed by n and p type silicon or III-V group material; and forming a Peltier junction on the isolation layer to connect the first and the second semiconductors, thereby forming the Peltier diodes, wherein electricity is applied to the Peltier diodes for transferring heat.

The material of the conductive pattern includes semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb. The first and second semiconductors are formed by ion implantation. The substrate includes glass, a surface of semiconductor device package, a surface of a cooling pad, a surface of a warming pad, a surface of a cooling container, a surface of a warming t container. The material of the Peltier junction include semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb.

A method of forming Peltier diodes comprises providing a substrate; forming a conductive pattern over the substrate; forming a semiconductor layer over the conductive pattern, followed by forming a first and a second semiconductors by implanting the semiconductor layer, wherein the first and second semiconductors are formed by silicon; and forming an isolation layer between the first and second semiconductors; forming a Peltier junction on the isolation layer to connect the first and the second semiconductors, thereby forming the Peltier diodes, wherein electricity is applied to the Peltier diodes for transferring heat.

The material of the conductive pattern includes semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb. The substrate include glass, a surface of semiconductor device package, a surface of a cooling pad, a surface of a warming pad, a surface of a cooling container, a surface of a warming t container. The material of the Peltier junction include semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb.

A method of forming Peltier diodes, comprises providing a substrate; forming a conductive pattern over the substrate; forming a semiconductor layer over the conductive pattern, followed by forming a first and a second semiconductors, wherein the first and second semiconductors are formed by III-V group material; and forming an isolation layer between the first and second semiconductors; forming a Peltier junction on the isolation layer to connect the first and the second semiconductors, thereby forming the Peltier diodes, wherein electricity is applied to the Peltier diodes for transferring heat.

The material of the conductive pattern includes semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb. The substrate includes glass, a surface of semiconductor device package, a surface of a cooling pad, a surface of a warming pad, a surface of a cooling container, a surface of a warming t container. The material of the Peltier junction includes semiconductor, metal, alloy, ceramic, conductive polymer, cabontube, or oxide containing metal, wherein the metal is one or more from Au, Zn, Ag, Pd, Pt, Rh, Ru, Cu, Fe, Ni, Co, Sn, Ti, In, Al, Ta, Ga, Ge and Sb.

The present invention discloses a heat dissipater for semiconductor assembly comprising at least one Peltier diode coupled to a least one surface of a semiconductor package having a die contain therein; an electricity lines coupled to the at least one Peltier diode; and wherein electricity is applied to the Peltier diode, current drives a heat transfer out of the semiconductor package. The heat dissipater further comprises a heat sink coupled to the at least one Peltier diode.

The present invention further discloses a cellular with a cross-processor data transfer interface, comprising: a first processor; a first cache coupled to the first processor; a second processor; a second cache coupled to the second processor; a cross-processor data transfer interface coupled to the first cache and the second cache, to determine how to transfer data, via the first processor and the second processor, and to assign task duties to the first processor or the second processor; a data transfer unit coupled to the cross-processor data transfer interface and one or more peripheral devices; a memory controller coupled to the cross-processor data transfer interface; a memory coupled to the memory controller; and a heat pumping device coupled to the first processor or the second processor. The heat pumping device includes at least one heat pipe or has an enclosed space filled with at least one phase change material. A heat sink is attached on the heat pumping device by an adhesion material or thermal conductive glue.

### BRIEF DESCRIPTION OF THE DRAWINGS

FIGS. 1A-1D illustrate the heat dissipation device for building window or vehicle window.

FIG. 2 illustrates the dissipation device for semiconductor component.

FIG. 3 illustrates the dissipation device for due semiconductor processors system.

FIG. 4 illustrates the dissipation device for semiconductor component.

FIG. 5 illustrates the method of the present invention.

### DETAILED DESCRIPTION

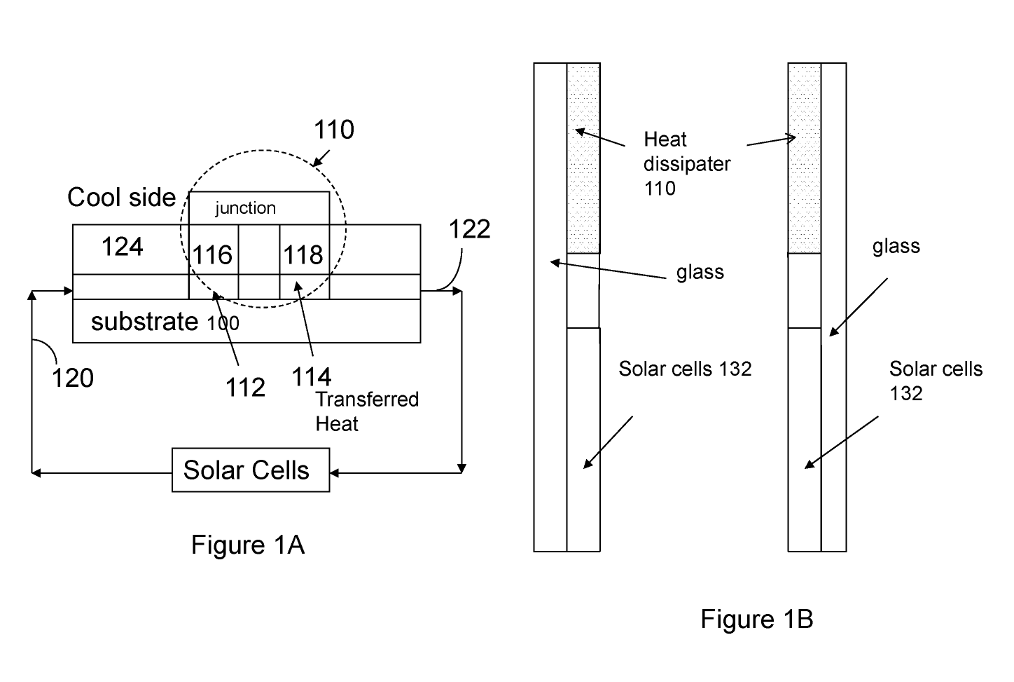

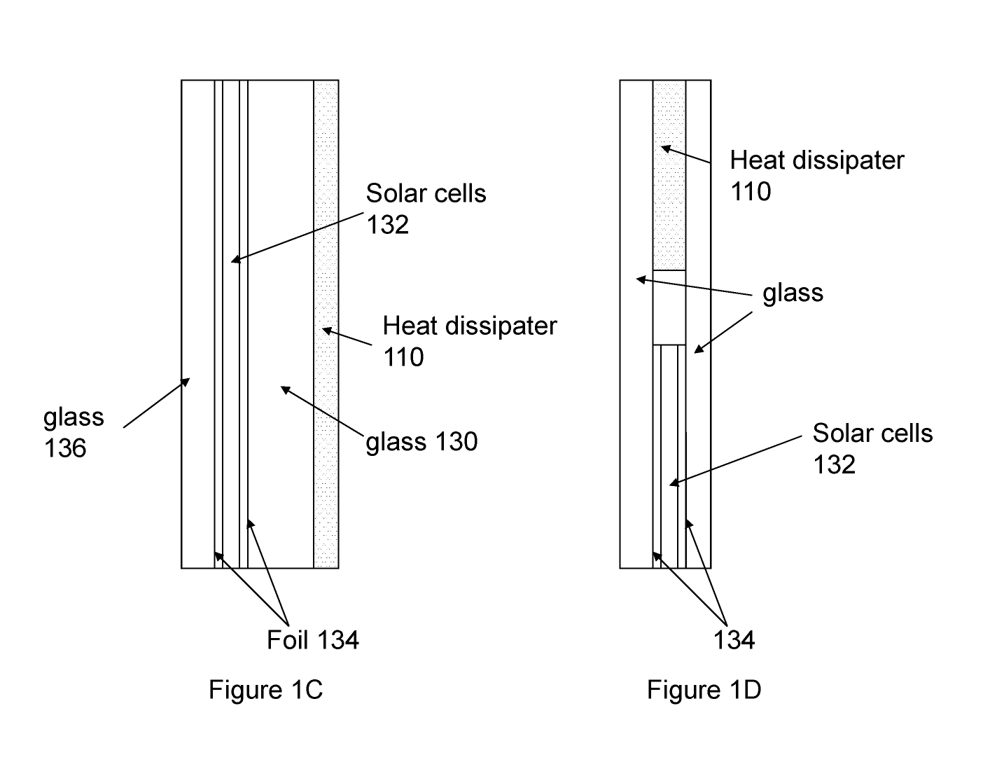

The present invention includes a substrate 100. As known, the heat dissipation device includes pluralities of Peltier diodes. Preferably, the substrate is substantially transparent, for example, PCB, glass, metal, alloy, ceramic, flexible polymer, plastic, quartz, wafer or the like. At least one Peltier diode 110 is formed on the substrate, as shown in FIG. 1A. The Peltier diode 110 includes the first electrode and the second electrode (first conductive patterns and the second conductive patterns) 112, 114, n-type and p-type semiconductors 116, 118 connected to each other at Peltier junction. In the embodiment, the n-type and p-type semiconductors 116, 118 are formed by thin film instead of bulk. The n-type and p-type semiconductors 116, 118 can be silicon layer or layer formed by III-V group elements. The pattern of the first electrode and the second electrode 112, 114, n-type and p-type semiconductors 116, 118 can be formed by etching, mask printing, mechanical punch, molding or coating. The conductive lines 120, 122 are coupled to the first conductive patterns 112 and the second conductive patterns 114, respectively. A heat difference is created between the two junctions. The current drives a heat transfer from one junction to the other, one junction cools off while the other heats up. Therefore, the heat may transfer from one side to another. An isolation material 124 may be filled between the first conductive pattern 112 and the second conductive pattern 114. It could be oxide, nitride, rubber, polymer, plastic or the like. Each of the pluralities of Peltier diodes 110 is formed on the substrate side by side.

The electrical energy is coupled to the conductive lines 120, 122. The power could be provided by electricity, battery or solar cell. In one application, the present invention may be used for an object, for instance, the window of building or house, the surface of cup, the surface of cooling pad or a vehicle. When the electricity is provided, the heat will be transferred from the inside of the object to the outside for cooling down the temperature within the object, thereby saving the energy. The power consumption is far lower than the conventional air condition. Preferably, the electricity is supplied by the solar cells set outside the building (vehicle). When the weather is hot, generally, the solar radiation is high and the efficiency of the solar cell is high. The solar cell could transfer the solar energy to electricity. When the temperature is not so high, the efficiency of the solar cell will automatically drop due to the radiation from the sun is lower, therefore, the present invention may achieve the purpose of self-adjustment heat dissipation. Subsequently, the present invention uses the electricity to cool down the temperature in the house or vehicle by the Peltier device (diode). The device may be employed as warmer when the electrode is reversed.

Preferably, the solar cells 132 maybe incorporated between glasses 130, 136, as shown in FIG. 1C, and FIG. 1D, or on single glass as FIG. 1B. The protection foils 134 may be set adjacent to the solar cell 132. The heat dissipater 110 may be attached adjacent to one of the glass or between the glass 130 and the glass 136.

FIG. 1A describe an embodiment of the present invention, the present invention comprises the conductive patterns 112, 114 formed over the object 100, a protection layer (not shown) is coated on the pattern. One example of the object 100 is semiconductor chip package, wind glass, rear glass, side glass of a vehicle, window of a building, a cup, a cooling, warming pad, cooling or warming container. Thus, the conductive lines 120, 122 are transparent if the substrate is transparent. In one example, a power source is coupled to the conductive pattern to remove fog, moisture on the glass.

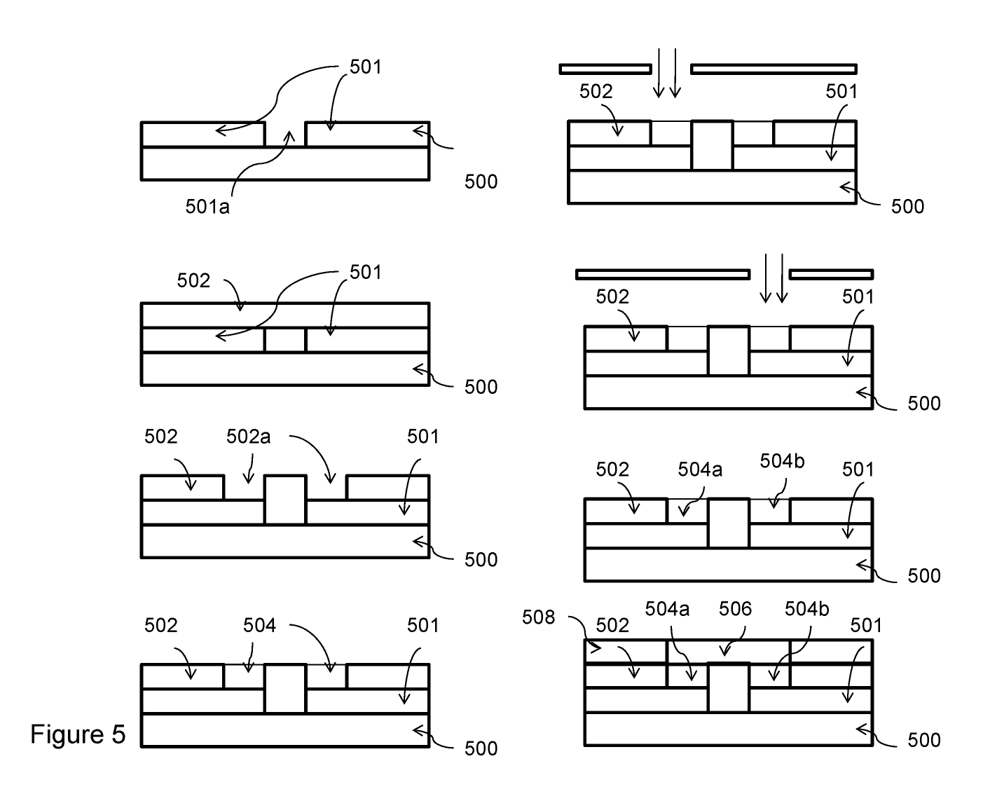

The method is disclosed as FIG. 5. A substrate 500 is provided. The substrate 500 may refer to the surface of an object or a planar supporting plate or material. Preferably, the substrate is substantially transparent, for example, PCB, glass, ceramic, flexible polymer, plastic, quartz, wafer or the like. The conductive pattern 501 is formed over the substrate 500 by inject-ink, mask-printing, mechanical stampings, (spin) coating, sputtering, or deposition (CVD or PVD) and etching. The conductive pattern 501 may be metal, alloy, conductive carbon, conductive polymer, ITO, ZnO or the like. Then, an isolation layer 502 is formed over the conductive pattern 501 and refilled within the gap 501a of the conductive pattern 501. The cavities 502a are created by etching the isolation layer with mask (not shown) or mechanical stamping. Then, the semiconductor layer 504 is refilled within the cavities 502a, followed by polishing the semiconductor layer 504 for planarization. The first and second type (n and p) semiconductors 504a, 504b are formed by implantation with a mask. Alternatively, the III-V material can be formed within the cavities 502a respectively as the first and second type semiconductors 504a, 504b.

Alternatively, the sequence of forming the first and second type semiconductors 504a, 504b and the isolation layer 502 can be changed. Namely, the semiconductor layer is formed over the substrate 500 by deposition, and mask-etching. Then, isolation layer 502 is refilled between the semiconductors after the first and second type semiconductors 504a, 504b are formed, followed by polishing the isolation layer 502 for planarization.

Subsequently, the Peltier junction 506 is formed over the isolation layer 502 to connect the first and second type semiconductors 504a, 504b, thereby forming the Peltier diode. The Peltier junction 506 may be metal, alloy, conductive corbon, conductive polymer, ITO, ZnO or the like. A protection layer 508 may be formed over the isolation layer 502 and maybe the Peltier junction 506 is also covered by the protection layer 508. The protection layer 508 may be ceramic, plastic, polymer, rubber, metal, alloy, oxide, nitride, glass, quartz or the like.

In one example, the present invention could be set on the window of a building to cool down the temperature within the building. In order to form on the glass, preferably, the material is transparent or substantially transparent. The material for the conductive pattern includes oxide containing metal, wherein the metal can be selected one or more from Au, Ag, Pt, In, Ga, Al, Sn, Ge, Sb, Bi, Zn, and Pd, for example, TIO, ZnO. Some conductive materials formed by the method are transparent, if the pattern is attached on the glass or window, one may see through the window or glass. In this case, the conductive layer, usually composed by a material includes oxide containing metal or alloy, wherein the metal is preferable to select one or more metals from Au, Zn, Ag, Pd, Pt, Rh, Ru, Cu, Fe, Ni, Co, Sn, Ti, In, Al, Ta, Ga, Ge and Sb. Some of the transparent material includes oxide containing Zn with Al₂O₃ doped therein. This shape is constructed by using an adequate mask during the forming process of the transparent conducting layer. The metal, alloy, ceramic, CNT (carbon nanotubes) and the conductive polymer could be used as the conductive pattern or conductive electrodes.

The method for forming the transparent conductive layer includes ion beam method for film formation at low temperature, for example, the film can be formed with receptivity lower than 3×10⁻⁴ Ω.cm at room temperature. Further, the RF magnetron sputtered thin film method could also be used. The transparent can be higher than 82%. It is well known in the field of forming thin film. Under the cost and production consideration, the method for forming, for example, indium tin oxide, could be formed at room temperature in wet atmosphere has an amorphous state, a desired pattern can be obtained at a high etching rate. After the film is formed and patterned, it is thermally treated at a temperature of about between 180 degree C. and 220 degree C. for about one hour to three hours to lower the film resistance and enhance its transmittance. Another formation is chemical solution coating method. The coating solution includes particles having an average particle diameter of 1 to 25 μm, silica particles having an average particle diameter of 1 to 25 μm, and a solvent. The weight ratio of the silica particles to the conductive particles is preferably in the range of 0.1 to 1. The conductive particles are preferably metallic particles of one or more metals selected from Au, Zn, Ag, Pd, Pt, Rh, Ru, Cu, Fe, Ni, Co, Sn, Ti, In, Al, Ta, Ga, Ge and Sb. The conductive particles can be obtained by reducing a salt of one or more kinds of the aforesaid metals in an alcohol/water mixed solvent. Heat treatment is performed at a temperature of higher than about 100 degree C. The silica particles may improve the conductivity of the resulting conductive film. The metallic particles are approximately contained in amounts of 0.1 to 5% by weight in the conductive film coating liquid.

The transparent conductive film can be formed by applying the liquid on a substrate, drying it to form a transparent conductive particle layer, then applying the coating liquid for forming a transparent film onto the fine particle layer to form a transparent film on the particle layer. The coating liquid for forming a transparent conductive layer is applied onto a substrate by a method of dipping, spinning, spraying, roll coating, flexographic printing or the like and then drying the liquid at a temperature of room temperature to about 90.degree. C. After drying, the coating film is curing by heated at a temperature of not lower than 100 degree C. or irradiated with an electromagnetic wave or in the gas atmosphere. The present invention uses the Peltier effect to create a heat flux between the junctions of two different types of semiconductor materials. It transfers heat from one side of the device to the other side with consumption of electrical energy.

A moisture removal power source may be coupled to the configuration via line for providing heat to the pattern to remove fog or moisture on the glass or window. Thus, in some case, the configuration includes dual functions including heat pump and acting as means for removing fog or moisture.

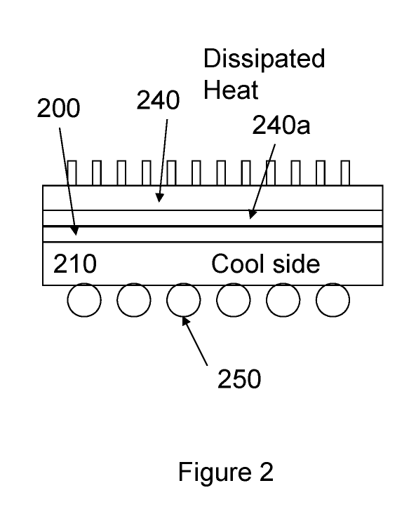

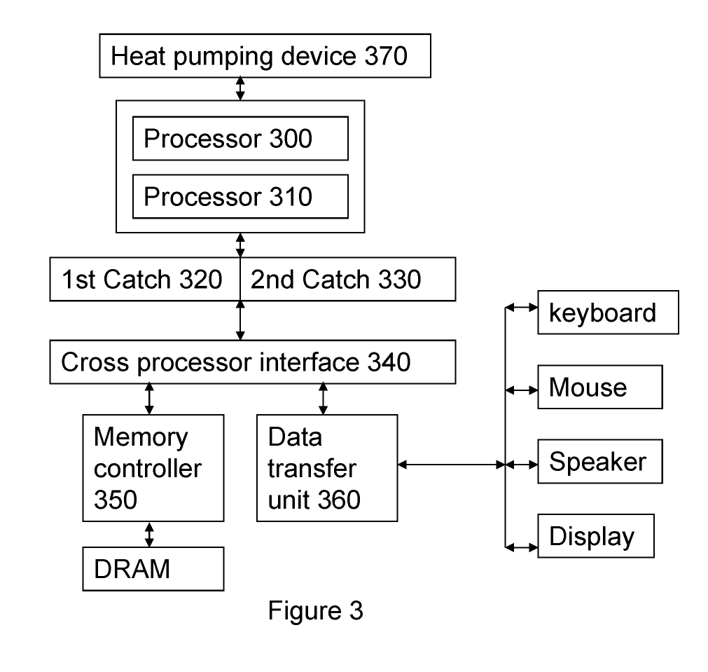

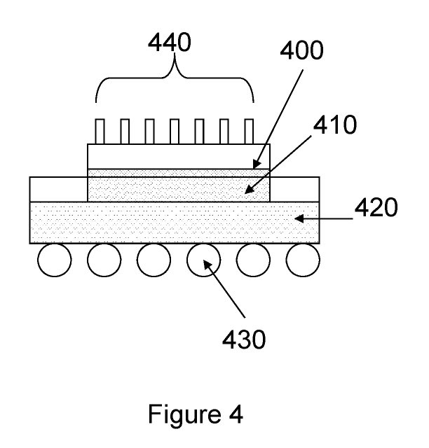

In another embodiment, the Peltier device is used to act the heat pump for processor for computer, notebook or mobile device such as cellar, PDA, GPS. Please refer to FIG. 2, the Peltier diodes 200 is coupled to the semiconductor chip package 210 having die contained therein by the method of FIG. 5. In one case, pluralities of Peltier diodes 200 are coated on the outside of BGA device having conductive balls 250. The flip-chip package is used for illustration only, not limits the scope of the present invention. The chip could be any device such as LED. At least one Peltier diodes 200 is formed on the semiconductor chip package 210. Most of the thermal is generated by the chip or processor of the computer, notebook or mobile device. The Peltier diode 200 can be formed by PVD, CVD, sputtering or coating. In order to improve the performance of thermal dissipation, a heat sink 240 may be attached on the Peltier diode 200 by adhesion or thermal conductive glue 240a. Accordingly, the heat sink is formed on the hot side, therefore, after the electricity is provided to the Peltier diode 200. The current drives a heat transfer from semiconductor component 210 to the heat sink side, one junction cools off while the other heats up. Especially, the scheme may be used to the due processors system, as shown in FIG. 3. In the case, the heat dissipater is formed outside of the semiconductor package assembly. Alternatively, referring to FIG. 4, the heat dissipater 400 formed by FIG. 5 is attached over the die 410 on a substrate 420 having conductive balls 430. The heat sink 440 is attached over the heat dissipater 400. In the flip-chip scheme, the heat dissipater 400 may be formed over the backside surface of the wafer before assembly. The backside surface refers to the surface without active area.

The electronic system includes a first processor 300 and a second processor 310. A first catch 320 and a second catch 330 are coupled to the first processor 300 and a second processor 310, respectively. A cross process data transfer interface 340 is coupled to the first catch 320 and a second catch 330. A memory controller 350 and a data transfer unit 360 are coupled to the cross process interface 340. The cross process interface 340 is used to determine how to transfer the date in/out to/from the first processor 300 and a second processor 310. The DRAM is coupled to the memory controller 350. A plurality of periphery devices such as Mic., speaker, keyboard, and mouse are coupled to the data transfer unit 360. A fan may be optionally coupled to the heat dissipation device mentioned in FIG. 2. If the system is single chip system, the cross-process interface is omitted. If the system is communication device, RF is necessary. Therefore, the present invention discloses a thermal solution for a computer system including a heat dissipater mentioned above coupled to the CPU to dissipate the thermal generated by the CPU.

In the present invention, the function of the “cross-processor data transfer interface” 340 is defined to determine how to transfer data, via the first processor and second processor, and to assign task duties to the first processor 300 or the second processor 310, i.e. the “cross-processor data transfer interface” 340 cross-connects the first processor 300 and the second processor 310. Thus, the “cross-processor data transfer interface” 340 allows the first processor 300 and the second processor 310 to simultaneously or parallelly operate due to the crossing interface, and the “cross-processor data transfer interface” 340 can assign tasks to either the first processor 300 or the second processor 310 due to the function of crossing interface.

The present invention comprises a heat pumping device 370 embedded in a portable device, shown in FIG. 3. The heat pumping device 370 may be coupled to the first processor 300 or the second processor 310 of the portable device. For example, the heat pumping device 370 includes at least one heat pipe and/or phase change material. In one embodiment, the heat pumping device 370 includes at least one heat pipe which is a heat transfer device that combines the principles of both thermal conductivity and phase transition to efficiently manage the transfer of heat between two solid interfaces. The heat pipe may be embedded into a portable device for thermal dissipation. In one example, a heat sink may be attached on the heat pipe, for example by an adhesion material or thermal conductive glue. The portable device is for example a smart phone, tablet, PDA, or any type wireless communication device.

At the hot interface of a heat pipe a liquid in contact with a thermally conductive solid surface turns into a vapor by absorbing heat from that surface. The vapor then travels along the heat pipe to the cold interface and condenses back into a liquid releasing the latent heat. The liquid then returns to the hot interface through either capillary action, centrifugal force, or gravity, and the cycle repeats. Due to the very high heat transfer coefficients for boiling and condensation, heat pipes are highly effective thermal conductors.

A typical heat pipe consists of a sealed pipe or tube made of a material that is compatible with the working fluid such as copper for water heat pipes, or aluminium for ammonia heat pipes. Typically, a vacuum pump is used to remove the air from the empty heat pipe. The heat pipe is partially filled with a working fluid and then sealed. The working fluid mass is chosen so that the heat pipe contains both vapor and liquid over the operating temperature range.

There are a number of other types of heat pipes which include flat heat pipes, Variable Conductance Heat Pipes (VCHPs), Pressure Controlled Heat Pipes (PCHPs), Diode Heat Pipes, Thermosyphons, and Rotating heat pipes.

In yet another embodiment, the heat pumping device 370 has an enclosed space filled with phase change material. The heat pumping device 370 with phase change material may be embedded into a portable device for thermal dissipation. In one example, a heat sink may be attached on the heat pumping device, for example by an adhesion material or thermal conductive glue.

When the temperature inside the housing of a portable device is higher than the phase transition temperature (such as melting temperature) of the phase change material, the heat pumping device 370 will store the heat inside the housing of the portable device without increasing temperature. Meanwhile, the state of the phase change material will be changed from solid to liquid, and the phase change material absorbs heat inside the housing of the portable device during the phase transition, such that temperature inside the housing of the portable device is maintained in the phase transition (melting) temperature of the phase change material. The phase change material of the invention is used to maintain the temperature inside the housing of the portable device, which is available temperature of operating allowed for the portable device, within the operating temperature range, to ensure the performance and lifetime of the portable device. Amount of the phase change material filled into the heat pumping device 370 may be adjusted according to actual applications. When the temperature inside the housing of the portable device is lower than the melting temperature of the phase change material, the heat pumping device 370 then releases heat energy. Meanwhile, the state of the phase change material will be changed from liquid to solid, and the phase change material releases latent heat inside the housing during the phase transition to the outside of the housing, until the state of phase change material returns to the original state (solid state).

The phase change material may be selected from paraffin wax (such as parafin C16-C18, parafin C16-C28, parafin C20-C33, parafin C22-C45), polyglycols, alkanes, inorganic salts, salts water compound and mixtures thereof, acid, fatty acids (such as capric acid, auric acid, myristic acid, palmitic acid, straric acid . . . ), salt solution, salt hydrate, sugar alcohol groups, polyolefin, polyester of low molecular weight, epoxy resin of low molecular weight or acrylate of low molecular weight.

If the heat pipe or the phase change material acts the heat pumping device, it is better than that the Peltier device acts the heat pump. It is because that the Peltier device will consume the power of the cellular.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure. While the preferred embodiment of the invention has been illustrated and described, it will be appreciated that various changes can be made therein without departing from the spirit and scope of the invention.

What is claimed is:

1. A cellular with a heat pumping device, comprising:
a first processor;
a first cache coupled to said first processor;
a second processor;
a second cache coupled to said second processor;
a heat pumping device coupled to said first processor or said second processor.

2. The cellular as claimed in claim 1, wherein said heat pumping device includes at least one heat pipe.

3. The cellular as claimed in claim 2, further comprising a heat sink attached on said at least one heat pipe by an adhesion material.

4. The cellular as claimed in claim 2, further comprising a heat sink attached on said at least one heat pipe by thermal conductive glue.

5. The cellular as claimed in claim 1, further comprising a cross-processor data transfer interface coupled to said first cache and said second cache, to determine how to transfer data, via said first processor and said second processor, and to assign task duties to said first processor or said second processor.

6. The cellular as claimed in claim 5, further comprising a data transfer unit coupled to said cross-processor data transfer interface and one or more peripheral devices.

7. The cellular as claimed in claim 6, further comprising a memory controller coupled to said cross-processor data transfer interface.

8. The cellular as claimed in claim 7, further comprising a memory coupled to said memory controller.

9. A cellular with a heat pumping device, comprising:
a first processor;
a first cache coupled to said first processor;
a second processor;
a second cache coupled to said second processor; and
a heat pumping device coupled to said first processor or said second processor, wherein said heat pumping device has an enclosed space filled with at least one phase change material.

10. The cellular as claimed in claim 9, wherein said at least one phase change material may be selected from paraffin wax, polyglycols, alkanes, inorganic salts, salts water compound and mixtures thereof, acid, fatty acids, salt solution, salt hydrate, sugar alcohol groups, polyolefin, polyester of low molecular weight, epoxy resin of low molecular weight or acrylate of low molecular weight.

11. The cellular as claimed in claim 9, further comprising a heat sink attached on said heat pumping device by an adhesion material.

12. The cellular as claimed in claim 9, further comprising a heat sink attached on said heat pumping device by thermal conductive glue.

13. The cellular as claimed in claim 9, further comprising a cross-processor data transfer interface coupled to said first cache and said second cache, to determine how to transfer data, via said first processor and said second processor, and to assign task duties to said first processor or said second processor.

14. The cellular as claimed in claim 13, further comprising a data transfer unit coupled to said cross-processor data transfer interface and one or more peripheral devices.

15. The cellular as claimed in claim 14, further comprising a memory controller coupled to said cross-processor data transfer interface.

16. The cellular as claimed in claim 15, further comprising a memory coupled to said memory controller.
